(19) United States
(12) Patent Application Publication
(10) Pub. No.: US 2009/0267229 A1
(43) Pub. Date: Oct. 29, 2009

(54) CHIP PACKAGE STRUCTURE

(76) Inventor: Hung-Che SHEN, Hsinchu (TW)

Correspondence Address: Muncy, Geissler, Olds & Lowe, PLLC, P.O. BOX 1364, FAIRFAX, VA, 22038-1364, US

(21) Appl. No.: 12/212,173

(22) Filed: Sep. 17, 2008

(30) Foreign Application Priority Data
Apr. 24, 2008 (TW) 097115044

(51) Int. Cl. H01L 23/488

(52) U.S. Cl. 257/737; 257/E23.023

(57) ABSTRACT

A chip package structure is provided. The chip package structure comprises different layers of leads electrically connected to different circuits of a chip. The chip package structure comprises a chip and a flexible substrate layer. The chip has an active surface, a plurality of first pads, and a plurality of second pads. The first pads and the second pads are disposed on the active surface. The flexible substrate layer has a first conductive layer, a second conductive layer, a first surface, and a second surface opposite the first surface. The flexible substrate layer has an opening defined therein. The first conductive layer is formed on the first surface of the flexible substrate layer. The first conductive layer includes a plurality of first leads. The first leads electrically connect to the first pads. The second conductive layer is formed on the second surface of the flexible substrate layer. The second conductive layer includes a plurality of second leads. The second leads extend inwards into the opening and electrically connect to the second pads through the opening.

This application claims priority to Taiwan Patent Application No. 097115044 filed on Apr. 24, 2008, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to a chip package structure. More particularly, the present invention relates to a chip package structure having a plurality of layers of leads and flexible substrate layers.

2. Descriptions of the Related Art

After being produced, a semiconductor chip must be packaged together with a conductive structure into a chip package structure in order for the circuits thereon to function properly. Wiring bonding, bump bonding, leadframes or the like may be used to connect the chip to the conductive structure. With the development of the semiconductor technology, advanced manufacturing processes have allowed of the production of smaller chips with more sophisticated functions. As a result, there needs to be more input/output (I/O) electrical connection terminals for the chip, i.e., the conductive structure must have a larger pin count.

FIG. 1 is a schematic view of a chip package structure disclosed in the prior art. The chip package structure 1 comprises a chip 11, a flexible substrate layer 12 and a conductive layer 13. The chip 11 has an active surface 14, a plurality of pads 15 and a plurality of bumps 16. Both the pads 15 and the bumps 16 are disposed on the active surface 14, in which the bumps 16 are formed on the pads 15 respectively. The flexible substrate layer 12 has a first surface 17 and defines an opening 18. The conductive layer 13 is formed on the first surface 17 of the flexible substrate layer 12. The conductive layer 13 comprises a plurality of leads 19 which are extended into the opening 18 for electrical connection to the bumps 16.

The chip package structure of the prior art is disadvantageous in that there is only a row of bumps on either side of the chip respectively, and the disposition of more I/O terminals can only be accomplished by enlarging the area of the chip to arrange more I/O terminals. This leads to the degradation of a percentage of circuits on the chip, causing an unnecessary increase in production costs.

Another solution arranges two rows of electrical terminals on either side of the chip and conductive paths for the connection between the electrical terminals and the conductive layer of the flexible substrate layer are provided through both inner lead bonding and wire bonding processes.

However, the above process is rather complex and leads to increased difficulties in implementation. Furthermore, there are bonding interfaces between the wires and the conductive layer as well as between the wires and the electrical terminals in the wire bonding process, so there is high resistivity formed therebetween, which is unfavorable for electrical conduction.

In view of this, it is highly desirable in the art to provide an improved chip package structure that provides more I/O electrical connection terminals to allow more electrical connections.

### SUMMARY OF THE INVENTION

One objective of this invention is to provide a chip package structure with a flexible substrate layer. The flexible substrate layer comprises a first conductive layer and a second conductive layer which are electrically connected to a plurality of first pads and a plurality of second pads of a chip respectively. Through the first conductive layer and the second conductive layer, connection with more chip circuits or circuits with different functions in a single chip is achievable, which further allows a more functionally complex chip.

Another objective of this invention is to provide a chip package structure with a first flexible substrate layer and a second flexible substrate layer. A first conductive layer is formed on the first surface of the first flexible substrate layer, while a second conductive layer is formed on the first surface of the second flexible substrate layer. The first conductive layer and the second conductive layer can be electrically connected to a plurality of first pads and a plurality of second pads of a chip respectively. Through the first conductive layer and the second conductive layer, connection with more chip circuits or circuits of different functions in a single chip is achievable, which further allows a more functionally complex chip. Increasing the number of flexible substrate layers and conductive layers can increase the number of leads of chip package structures for electrically connection. At the same time, the number of flexible substrate layers can be increased depending on the number of chip pads needed in a particular application.

The chip circuits described above may be circuits with either the same or different functions, such as circuits with different functions in a system-on-chip (SoC) or circuits with the same function in an LCD driver chip.

This invention discloses a chip package structure adapted to provide more electrical connections. The chip package structure comprises a chip and a flexible substrate layer. The chip has an active surface, a plurality of first pads and a plurality of second pads. Both the first pads and the second pads are disposed on the active surface. The flexible substrate layer has a first conductive layer, a second conductive layer, a first surface, and a second surface opposite the first surface. The flexible substrate layer defines an opening therein. The first conductive layer is formed on the first surface of the flexible substrate layer. The first conductive layer comprises a plurality of first leads electrically connected to the first pads. The second conductive layer is formed on the second surface of the flexible substrate layer, while the second conductive layer comprises a plurality of second leads which are extended inwards into the opening to be electrically connected to the second pads through the opening.

This invention further discloses a chip package structure adapted to provide more electrical connections. The chip package structure comprises a chip, a first flexible substrate layer and a second flexible substrate layer. The chip has an active surface, a plurality of first pads and a plurality of second pads, wherein both the first pads and the second pads are disposed on the active surface. The first flexible substrate layer has a first surface and a second surface opposite the first surface, and defines a first opening therein. The first conductive layer is formed on the first surface of the first flexible substrate layer. The first conductive layer comprises a plurality of first leads adapted to be electrically connected to the first pads. The second flexible substrate layer has a first surface and a second surface opposite the first surface, in which the first surface of the second flexible substrate layer faces the second surface of the first flexible substrate layer. The second flexible substrate layer is formed on the first flexible substrate layer. The second flexible substrate layer defines a chip bonding area on the first surface thereof, with the chip bonding area located in the first opening. A second conductive layer is formed on the first surface of the second flexible substrate layer, and the second conductive layer comprises a plurality of second leads which are extended inwards into the first opening to be electrically connected to the second pads through the first opening.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of a chip package structure of the prior art;

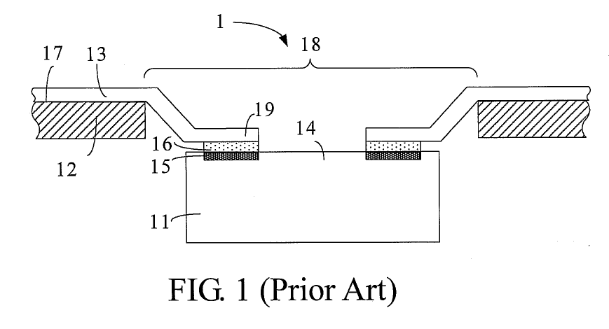

FIG. 2 is a schematic view of an embodiment of a chip package structure of this invention;

FIG. 3 is a schematic view of another embodiment of a chip package structure of this invention; and

FIG. 4 is a schematic view of yet another embodiment of a chip package structure of this invention.

### DESCRIPTION OF THE PREFERRED EMBODIMENT

Hereinafter, this invention will be explained with reference to embodiments thereof, which provide a chip package structure that has multiple layers of leads for electrical connection with more circuits in a chip or with circuits of different functions. This overcomes the disadvantage of the chip package structure of the prior art. The chip circuits may be circuits with either the same or different functions, such as circuits with different functions in a system-on-chip (SoC) or circuits with the same function in an LCD driver chip.

However, these embodiments are not intended to limit this invention to any specific environment, applications or particular implementations described in these embodiments. Therefore, description of these embodiments is only intended to illustrate but not to limit this invention. It should be appreciated that, in the following embodiments and the attached drawings, elements not related directly to this invention are omitted from depiction. For ease of understanding, dimensional relationships among the individual elements are depicted in an exaggerative manner. Furthermore, in the attached drawings, elements in bilateral symmetry to each other represent elements with the same features, and for simplicity of the drawings and for convenience of description, identical reference numerals will not be repeated.

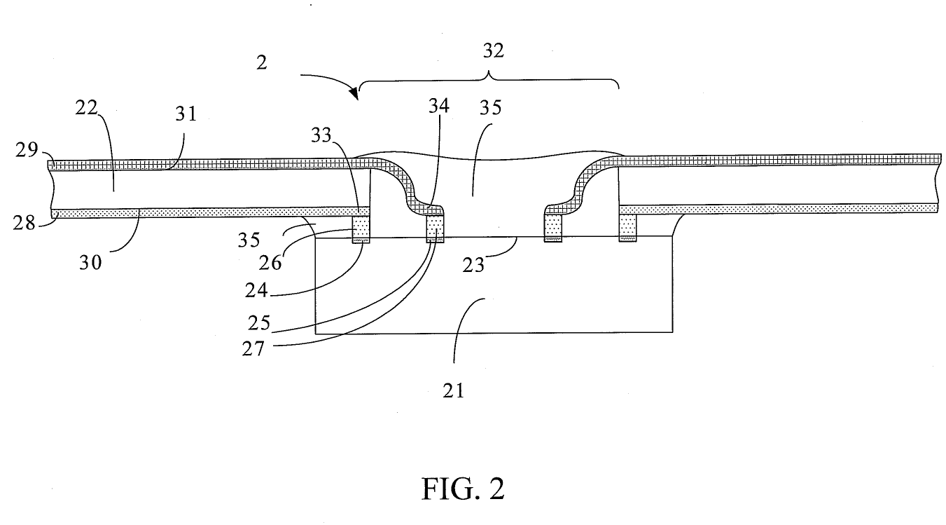

FIG. 2 is a schematic view of an embodiment of a chip package structure of this invention. The chip package structure 2 comprises a chip 21, a flexible substrate layer 22, a first conductive layer 28, a second conductive layer 29, a plurality of first bumps 26, a plurality of second bumps 27 and an encapsulant 35. The chip 21 has an active surface 23, a plurality of first pads 24 and a plurality of second pads 25. The first pads 24 and the second pads 25 are disposed on the active surface 23. The plurality of first bumps 26 and the plurality of second bumps 27 are formed on the first pads 24 and the second pads 25 respectively. It should be appreciated that, this embodiment is just a preferred embodiment; and other embodiments where a plurality of conductive layers is used for a packaging process, such as embodiments where a plurality of conductive layers is directly connected to the pads or embodiments where a plurality of conductive layers is directly connected to the pads and/or bumps respectively, all fall within the scope of this invention.

In particular, the first bumps 26 and the second bumps 27 of this embodiment may be made of materials selected from a group consisting of gold (Au), copper (Cu), aluminum (Al), nickel (Ni), and combinations thereof. However, in other embodiments, the materials thereof are not merely limited thereto, and other metal materials may be used instead as the bump materials to accomplish the electrical connection.

The flexible substrate layer 22 has a first surface 30 and a second surface 31 opposite the first surface 30, and defines an opening 32 therein. In this embodiment, the opening 32 exposes the second bumps 27 when the flexible substrate layer 22 is bonded with the chip 21. Furthermore, as described above, in other embodiments without the bumps, the opening 32 exposes the second pads 25 directly. In particular, the flexible substrate layer 22 of this embodiment is made of a material selected from a group consisting of polyimide and polyethylene terephthalate (PET). However, in other embodiments, the materials thereof are not merely limited thereto, and other flexible chemical compounds may be used instead for the flexible substrate layer 22.

In this embodiment, the first conductive layer 28 and the second conductive layer 29 are made of Cu. However, in other embodiments, the materials thereof are not merely limited thereto. For example, other metal materials such as Au, Al or Ni may be used instead for the conductive layers for electrical conduction. The first conductive layer 28 is formed on the first surface 30 of the flexible substrate layer 22. The first conductive layer 28 comprises a plurality of first leads 33 electrically connected to the first pads 24. More specifically, the first leads 33 are electrically connected to the first pads 24 via the first bumps 26. The second conductive layer 29 is formed on the second surface 31 of the flexible substrate layer 22. The second conductive layer 29 comprises a plurality of second leads 34, which are extended into the opening 32 to be electrically connected to the second pads 25 through the opening 32. More specifically, in this embodiment, the second leads 34 may further be electrically connected to the second pads 25 via the second bumps 27. In other embodiments where bumps are not required, the second leads 34 may be electrically connected to the second pads 25 directly. The flexible substrate layer 22, the first conductive layer 28 and the second conductive layer 29 of this embodiment may be implemented by a monolayer substrate layer with conductive layers disposed on both surfaces.

The encapsulant 35 is configured to cover the first bumps 26 and the first leads 33 at a interconnect juncture and to cover the second bumps 27 and the second leads 34 at a interconnect juncture. In particular, the material of the encapsulant 35 in this embodiment is epoxy resin. However, in other embodiments, the material of the encapsulant 35 is not merely limited thereto. For example, other chemical compounds with insulation and weather-proof properties may be used instead to cover the junctures to prevent short-circuit at the junctures for insulation purposes.

In this way, the first leads 33 and the second leads 34 can be electrically connected with different circuits on the chip 21. In other embodiments, if the chip 21 is a system-on-chip (SOC) or an integrated power electronic chip with circuits of different voltage requirements or circuits independent from each other, the chip package structure with multiple layers of leads can be used to accomplish the circuit design to provide conductive paths for circuits of different functions on the chip.

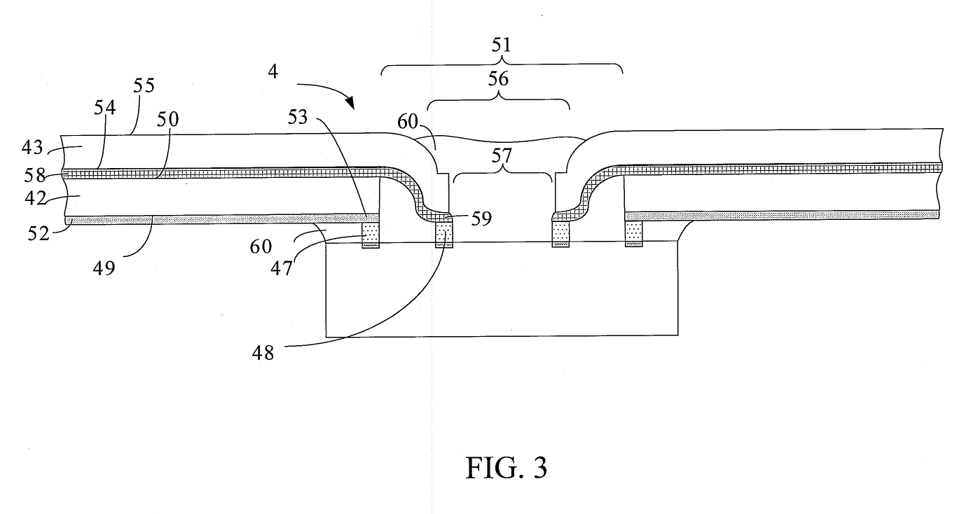

FIG. 3 is a schematic view of another embodiment of a chip package structure of this invention. The chip package structure 4 is different from the chip package structure 2 primarily in that the chip package structure 4 comprises two flexible substrate layers, namely, a first flexible substrate layer 42 and a second flexible substrate layer 43.

The second flexible substrate layer 43 has a first surface 54 and a second surface 55 opposite the first surface 54. The first surface 54 of the second flexible substrate layer 43 faces the second surface 50 of the first flexible substrate 42. On the first surface 54 thereof, the second flexible substrate layer 43 defines a chip bonding area 56 located in the first opening 51. The second flexible layer 43 further defines a second opening 57 located in the chip bonding area 56. The encapsulant 60 via the second opening 57 is configured to cover the first bumps 47 and the first leads 53 at a interconnect juncture and to cover the second bumps 48 and the second leads 59 at a interconnect juncture. In particular, the material of the encapsulant 60 in this embodiment is epoxy resin. However, in other embodiments, the material of the encapsulant 60 is not merely limited thereto; for example, other chemical compounds may be used instead to cover the junctures to prevent short-circuit at the junctures for insulation purposes. Other portions of the chip package structure 4 are identical to those of the chip package structure 2 and thus, will not be described again herein. The first flexible substrate layer 42, the second flexible substrate layer 43, the first conductive layer 52 and the second conductive layer 58 of this embodiment may be implemented by a monolayer substrate layer with the conductive layers disposed on both surfaces in combination with an additional flexible substrate layer, or by two monolayer substrate layers with a single conductive layer disposed on one surface respectively.

It should be noted that the first conductive layer 52 and the second conductive layer 58 of this embodiment are supported by the first flexible substrate layer 42 and the second flexible substrate layer 43 respectively, so the first leads 53 and the second leads 59 will not be suspended in the first opening 51, and thereby the shifting or fracture of the leads is prevented.

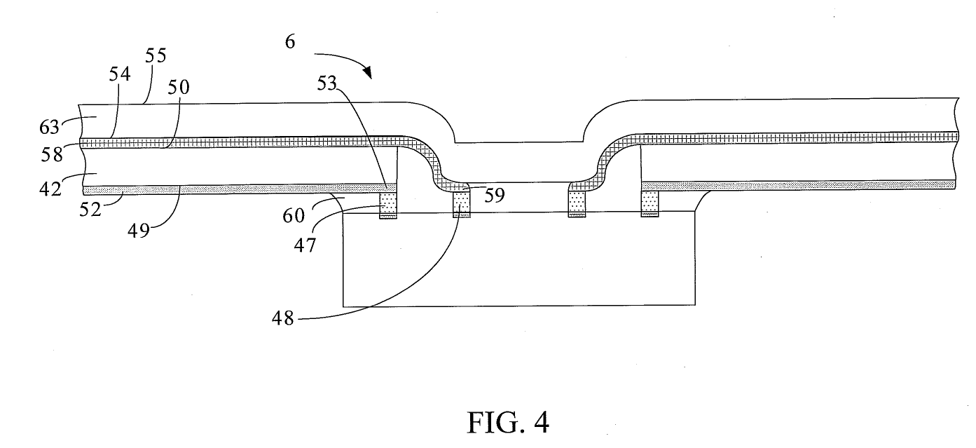

FIG. 4 is a schematic view of yet another embodiment of a chip package structure of this invention. The chip package structure 6 is different from the chip package structure 4 primarily in that, the second flexible substrate layer 63 of the chip package structure 6 defines no opening. Other portions of the chip package structure 6 are identical to those of the chip package structure 4 and thus, will not be described again herein.

The chip package structure of this invention may be applied in a packaging process involving more than two flexible substrate layers, in order to comply with chips with multiple rows of pads or bumps to provide conductive paths for the circuits of the chips. Therefore, this invention is not limited by the number and arrangement of the pads or bumps.

The chip package structure of this invention may be applied in a chip packaging process using a monolayer flexible substrate that has conductive layers on both surfaces, e.g., a chip packaging process utilizing a dual-side copper foil substrate. Alternatively, the chip package structure of this invention may be applied in a chip packaging process using multiple monolayer flexible substrates that have a single conductive layer on one surface, e.g., a chip packaging process utilizing a single-sided copper foil substrate. Furthermore, the chip package structure of this invention may be implemented by, for example, a tape of tape carrier package (TCP) already with an opening, or a film of chip on film (COF) package with an additional opening formed therein.

The chip package structure of this invention uses conductive layers on a flexible substrate as leads to electrically connect the circuits of a chip. This only necessitates simply the addition of conductive layers without the need of significant changes in the manufacturing process, thus reducing the manufacturing cost. The chip package structure of this invention employs multiple layers of flexible substrates to provide more electrical connection terminals in a limited area. Moreover, depending on the design of the chip, different conductive layers may be used as conductive paths for circuits with the same or different functions in the chip.

As compared to the chip package structure of the prior art which only uses a conductive layer on a single flexible substrate layer for electrical connection, this invention removes limitations in terms of the manufacturing process by using plurality of conductive layers, thus overcoming the disadvantage of the prior art chip package structure.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A chip package structure, comprising:
a chip, having an active surface, a plurality of first pads, and a plurality of second pads, the first pads and the second pads being disposed on the active surface;
a flexible substrate layer, having a first surface, and a second surface opposite the first surface, and the flexible substrate layer defining an opening therein;
a first conductive layer, being formed on the first surface of the flexible substrate layer, the first conductive layer having a plurality of first leads, the first leads being electrically connected to the first pads; and
a second conductive layer, being formed on the second surface of the flexible substrate layer, the second conductive layer having a plurality of second leads, the second leads extending inward into the opening and being electrically connected to the second pads through the opening.

2. The chip package structure as claimed in claim 1, wherein the chip further comprises a plurality of first bumps, and a plurality of second bumps, being formed on the first pads and the second pads respectively.

3. The chip package structure as claimed in claim 2, wherein the opening defined by the flexible substrate layer, when the flexible substrate layer is bonded with the chip, exposes the second bumps.

4. The chip package structure as claimed in claim 2, wherein the bumps is made of materials selected from a group consisting of gold, copper, aluminum, nickel, and the combination thereof.

5. The chip package structure as claimed in claim 2, wherein the first leads are electrically connected to the first bumps correspondingly.

6. The chip package structure as claimed in claim 2, wherein the second leads are electrically connected to the second bumps correspondingly.

7. The chip package structure as claimed in claim 2, further comprising an encapsulant, in which the encapsulant is configured to cover the first bumps and the first leads at a interconnect juncture, and to cover the second bumps and the second leads at a interconnect juncture.

8. The chip package structure as claimed in claim 1, wherein the flexible substrate layer is made of materials selected from a group consisting of Polyimide and polyethylene terephthalate (PET).

9. The chip package structure as claimed in claim 1, wherein the first conductive layer and the second conductive layer are made of copper.

10. A chip package structure, comprising:
a chip, having an active surface, a plurality of first pads, and a plurality of second pads, wherein the first pads and the second pads are disposed on the active surface;
a first flexible substrate layer, having a first surface and a second surface opposite the first surface, and the first flexible substrate layer defining a first opening therein;
a first conductive layer, being formed on the first surface of the first flexible substrate layer, the first conductive layer having a plurality of first leads, the first leads being adapted to be electrically connected to the first pads;
a second flexible substrate layer, having a first surface and a second surface opposite the first surface, the first surface of the second flexible substrate layer being facing the second surface of the first flexible substrate layer, the second flexible substrate layer being formed on the first flexible substrate layer, the second flexible substrate layer defining a chip bonding area on the first surface thereof, the chip bonding area being located in the first opening; and
a second conductive layer, being formed on the first surface of the second flexible substrate layer, the second conductive layer having a plurality of second leads, the second leads extending inward into the first opening and being electrically connected to the second pads through the first opening.

11. The chip package structure as claimed in claim 10, wherein the second flexible substrate layer further defines a second opening located in the chip bonding area.

12. The chip package structure as claimed in claim 10, wherein the chip further comprises a plurality of first bumps and a plurality of second bumps, being formed on the first pads and the second pads respectively.

13. The chip package structure as claimed in claim 12, wherein the first opening defined by the first flexible substrate layer, when the first flexible substrate layer is bonded with the chip, exposes the second bumps.

14. The chip package structure as claimed in claim 12, wherein the first bumps and the second bumps are made of materials selected from a group consisting of gold, copper, aluminum, nickel, and combination thereof.

15. The chip package structure as claimed in claim 12, wherein the first leads are electrically connected to the first bumps correspondingly.

16. The chip package structure as claimed in claim 12, wherein the second leads are electrically connected to the second bumps correspondingly.

17. The chip package structure as claimed in claim 12, further comprising an encapsulant, in which the encapsulant is configured to cover the first bumps and the first leads at a interconnect juncture, and to cover the second bumps and the second leads at a interconnect juncture.

18. The chip package structure as claimed in claim 10, wherein the first flexible substrate layer and the second flexible substrate layer are made of materials selected from a group consisting of Polyimide and polyethylene terephthalate (PET).

19. The chip package structure as claimed in claim 10, wherein the first conductive layer and the second conductive layer are made of copper.

20. The chip package structure as claimed in claim 10, wherein the second conductive layer is attached on the second surface of the first flexible substrate layer.
